(19) United States
(12) Patent Application Publication
(10) Pub. No.: US 2009/0090544 A1
(43) Pub. Date: Apr. 9, 2009

(54) System and Method for Substrate with Interconnects and Sealing Surface

(75) Inventors: Jay Scott Rawot, Allen, TX (US); James Charles Williams, Murphy, TX (US); David Kent Finfrock, Richardson, TX (US)

Correspondence Address: BAKER BOTTS L.L.P., 2001 ROSS AVENUE, SUITE 600, DALLAS, TX, 75201-2980, US

(73) Assignee: Marlow Industries, Inc., Dallas, TX (US)

(21) Appl. No.: 12/209,758

(22) Filed: Sep. 12, 2008

Related U.S. Application Data
(60) Provisional application No. 60/977,872, filed on Oct. 5, 2007.

(51) Int. Cl. H05K 1/18; H05K 3/32

(52) U.S. Cl. 174/260; 29/832

(57) ABSTRACT

A method includes providing a base. At least one lead is deposited on the base, the at least one lead including a trace of electrically conductive material having a first end and a second end. A dielectric layer is deposited on a portion of the at least one lead between the first end and the second end. A sealing surface is deposited on a portion of the dielectric layer, the sealing surface including a contiguous shape of metal separating an enclosed area of the base located inside the contiguous shape from an open area of the base located outside the contiguous shape. The first end of the at least one lead is located in the enclosed area and the second end of the at least one lead is located in the open area. Moreover, the dielectric layer electrically insulates the at least one lead from the sealing surface.

### CROSS REFERENCE TO RELATED APPLICATIONS

This application claims the benefit under 35 U.S.C. §119(e) of U.S. Provisional Application No. 60/977,872, entitled “System and Method for a Thermoelectric Module Substrate with Interconnects and Sealing Surface,” filed Oct. 5, 2007.

### TECHNICAL FIELD

The present disclosure relates to thermoelectric devices and more specifically to a system and method for a substrate with interconnects and sealing surface.

### BACKGROUND

Thermoelectric modules may be used to cool devices such as detectors that are used in a wide variety of applications. To aid these units in functioning effectively and reliably the detectors and thermoelectric modules may be kept in an inert atmosphere or in a vacuum. Accordingly these devices may be covered and sealed to allow the final device to be smaller and portable.

### SUMMARY

The present disclosure relates generally to a system and method for a substrate with interconnects and a sealing surface. In particular embodiments, a method for manufacturing a substrate with interconnects and a sealing surface includes providing a base composed of a first electrically insulating material. At least one lead is deposited on the base, the at least one lead including a trace of electrically conductive material having a first end and a second end. A dielectric layer is deposited on a portion of the at least one lead between the first end and the second end, the dielectric layer including a coating of a second electrically insulating material. A sealing surface is deposited on a portion of the dielectric layer, the sealing surface including a contiguous shape of metal separating an enclosed area of the base located inside the contiguous shape from an open area of the base located outside the contiguous shape. The first end of the at least one lead is located in the enclosed area and the second end of the at least one lead is located in the open area. Moreover, the dielectric layer electrically insulates the at least one lead from the sealing surface.

In particular embodiments, the dielectric layer may generally correspond to the contiguous shape and may separate the base and the at least one lead from the sealing surface.

In particular embodiments, the method further includes mounting one or more electrical components to the base inside the enclosed area and coupling one of the one or more electrical components to the at least one lead.

In particular embodiments, the method further includes providing a cap including a perimeter edge that generally corresponds in configuration to the contiguous shape.

In particular embodiments, the method further includes placing the cap over the one or more electrical components and fusing the perimeter edge of the cap to the sealing surface. As an example and not by way of limitation, the perimeter edge of the cap may be fused to the sealing surface using heat.

In particular embodiments, the base may include a flexible material.

In particular embodiments, the method further includes depositing a patterned metallization inside the sealed area that, once coupled to an electrical component, electrically interconnects one or more elements of the electrical component.

In particular embodiments, the one or more electrical components may include an electrooptic device.

In particular embodiments, the cap may include a window of generally transparent material operable to transmit light from a light source from a first side of the window to a second side of the window.

Technical advantages of particular embodiments of the present disclosure may include eliminating the need for cooler leads to be inserted into a sealed package (e.g., one or more electrical components housed inside of a sealed enclosure) through holes in the sealed package. Further technical advantages of particular embodiments of the present disclosure may include improved heat conduction between a thermoelectric module and a substrate due to the ability to directly couple the thermoelectric module to the substrate.

Other technical advantages of the present disclosure will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present disclosure and its advantages, reference is now made to the following descriptions, taken in conjunction with the accompanying drawings, in which:

FIG. 1 illustrates an example substrate with interconnects and sealing surface according to an example embodiment of the present disclosure;

FIG. 2 illustrates a cross-sectional view of a portion of the substrate with interconnects and sealing surface illustrated in FIG. 1;

FIG. 3 illustrates an isometric view of an electrical component mounted to the substrate with interconnects and sealing surface illustrated in FIG. 1 according to an example embodiment of the present disclosure; and

FIG. 4 illustrates an example method for producing a substrate with interconnects and sealing surface according to an example embodiment of the present disclosure.

### DETAILED DESCRIPTION OF EXAMPLE EMBODIMENTS

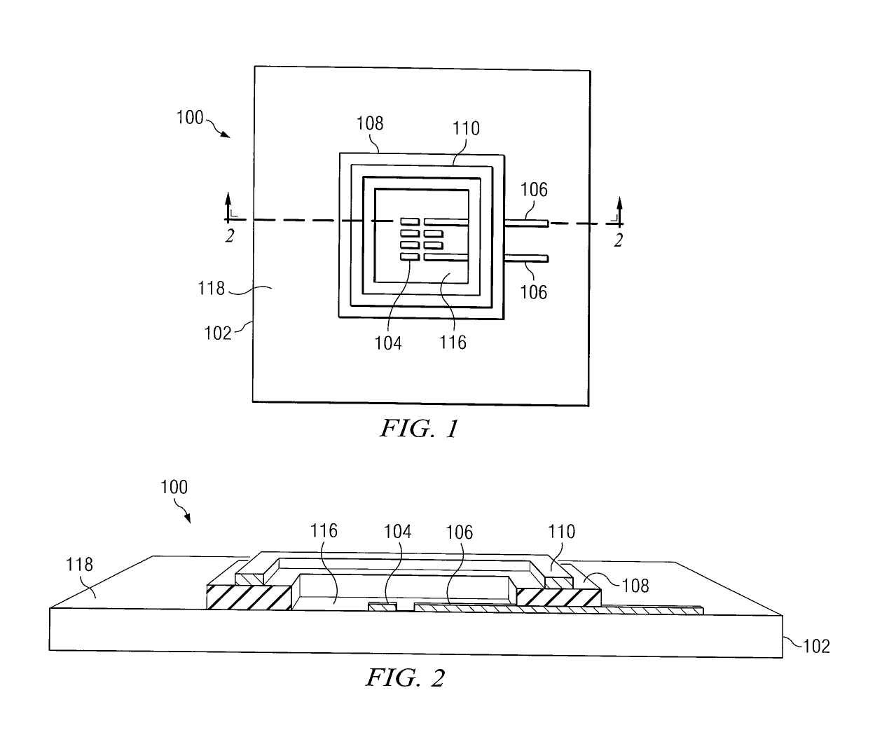

FIG. 1 illustrates a substrate 100. Substrate 100 includes a base 102, upon which reside a patterned metallization 104, one or more leads 106, a dielectric layer 108, and a sealing surface 110. In particular embodiments, patterned metallization 104 is surrounded by dielectric layer 108 and sealing surface 110. In particular embodiments, dielectric layer 108 may insulate leads 106 from sealing surface 110. Leads 106 may pass under dielectric layer 108 and sealing surface 110 and may, for example, supply power from a power source located outside of sealing surface 110 to one or more electrical components 112 located inside sealing surface 110. Leads 106 may further communicate data signals to and from the electrical components 112 located inside sealing surface 110 (e.g., in enclosed area 116), for example to control the electrical components 112 located inside sealing surface 110.

Leads 106 may be any deposition or trace of electrically conductive material capable of communicating electrical current with an electrical component 112 located inside sealing surface 110. Depending upon design, leads 106 may be composed of copper, nickel, or other metal, and leads 106 may be deposited on base 102 by screen printing, dispensing, sputtering, electroplating, or other suitable deposition technique.

In particular embodiments, leads 106 may supply power from a power source located outside of sealing surface 110 to one or more electrical components 112 located inside sealing surface 110. As an example and not by way of limitation, electrical component 112 may be a thermoelectric module mounted inside sealing surface 110 to which leads 106 may supply current from a power source located outside of sealing surface 110. As another example and not by way of limitation, multiple electrical components 112 may be mounted inside sealing surface 110, each electrical component 112 being supplied power from its own set of leads 106. For example, a first set of leads 106 may supply power to a thermoelectric module and a second set of leads 106 may supply power to a temperature sensor located inside sealing surface 110. As yet another example and not by way of limitation, an electrical component 112 located inside sealing surface 110 may include multiple sets of leads (e.g., a first set of leads to power electrical component 112 and a second set of leads 106 to communicate data with electrical component 112).

In particular embodiments, the position of leads 106 may be custom designed to suit the topology of a preconfigured electrical component (e.g., to align with the power inputs of a prefabricated circuit). One of ordinary skill in the art will appreciate that the above-described compositions, methods of deposition, number, and configurations of leads 106 were presented for the sake of explanatory simplicity and will further appreciate that the present disclosure contemplates the use of any suitable composition, method of deposition, number, and configuration of leads 106 in order to communicate electrical current to or from one or more electrical components 112 located inside sealing surface 110.

Dielectric layer 108 may be any coating or layer or combination of coatings or layers capable of electrically insulating leads 106 from sealing surface 110. As an example and not by way of limitation, dielectric layer 108 may be ceramic, glass, plastic or metal oxide materials including but not limited to products like DuPont 5681, Heraeus IP9319D, Ferro 1903, or Metech 7600A. In particular embodiments, dielectric layer 108 may be deposited on base 102 by screen printing, dispensing, sputtering, electroplating, or other suitable deposition technique. Depending upon the material selected for dielectric layer 108 as well as the thickness of dielectric layer 108, dielectric layer 108 may be either rigid or flexible.

Dielectric layer 108 may be configured in any shape and size and may cover any suitable portion of leads 106 and any suitable portion of base 102. As an example and not by way of limitation, dielectric layer 108 could be a circle, a square, an oval, or one or more other contiguous or noncontiguous shapes. One of ordinary skill in the art will appreciate that the above-described compositions, methods of deposition, and configurations of dielectric layer 108 have been presented for the sake of explanatory simplicity and will further appreciate that the present disclosure contemplates the use of any suitable composition, method of deposition, and configuration of dielectric layer 108 in order to electrically insulate leads 106 from sealing surface 110.

Sealing surface 110 may be any coating or layer or combination of coatings or layers deposited on dielectric layer 108, base 102, or a combination thereof operable to allow another object (e.g., a cap 114) to be fused to substrate 100 by soldering, brazing, welding or other suitable fusion process including heat, pressure, electricity or a combination thereof. As an example and not by way of limitation, sealing surface 110 may be a layer of copper, nickel, or other metal, or combination of metals. In particular embodiments, sealing surface 110 may be deposited on substrate 100 by screen printing, dispensing, sputtering, electroplating, or other suitable deposition technique. Sealing surface 110 may be configured in any contiguous shape of any size and may cover portions of dielectric layer 108 and/or base 102. As an example and not by way of limitation, sealing surface 110 could be a circle, a square, an oval, or an irregular contiguous shape.

Depending upon design, a first portion of sealing surface 110 may reside on dielectric layer 108 and a second portion of sealing surface 110 may reside directly on base 102, or alternatively, all of sealing surface 110 may reside on top of dielectric layer 108. One of ordinary skill in the art will appreciate that the above-described compositions, methods of deposition, and configurations of sealing surface 110 have been presented for the sake of explanatory simplicity and will further appreciate that the present disclosure contemplates the use of any suitable composition, method of deposition, and configuration of sealing surface 110 in order to allow another object to be fused to substrate 100 by soldering, brazing, welding or other suitable fusion process including heat, pressure, electricity or a combination thereof.

Base 102 may be any fixture or combination of fixtures composed of one or more electrically insulating materials capable of acting as a substrate base for an electrical component. As an example and not by way of limitation, base 102 may a rigid plate composed of a thermally conducting and electrically insulating material (e.g., ceramic). As an additional example and not by way of limitation, base 102 may a flexible sheet composed of a thermally conducting and electrically insulating material. One of ordinary skill in the art will appreciate that the present disclosure contemplates the use of any suitable device or fixture composed of any suitable material to act as a base for the other components of substrate 100.

FIG. 2 illustrates a cross-sectional view of a portion of substrate 100 “cut” along one of leads 106. In particular embodiments, leads 106, dielectric layer 108, and sealing surface 110 are deposited on one side of base 102. Thus, in particular locations, one or more of these components (or a portion of one or more of these components) may reside on top of one another in a series of layers. As an example and not by way of limitation, in the illustrated embodiments, leads 106 may reside on base 102; dielectric layer 108 may reside on top of leads 106, and sealing surface 110 may reside on top of dielectric layer 108. By depositing the components of substrate 100 on base 102 in a series of layers, substrate 100 may be enabled to act as both the base of a sealed package and as a substrate for electrical component 112. One of ordinary skill in the art will appreciate that the interfaces between each of the components (e.g., the base 102 to lead 106 interface, the lead 106 to dielectric layer 108 interface, and the dielectric layer 108 to sealing surface 110 interface) may be substantially impenetrable (e.g., impenetrable to air and water).

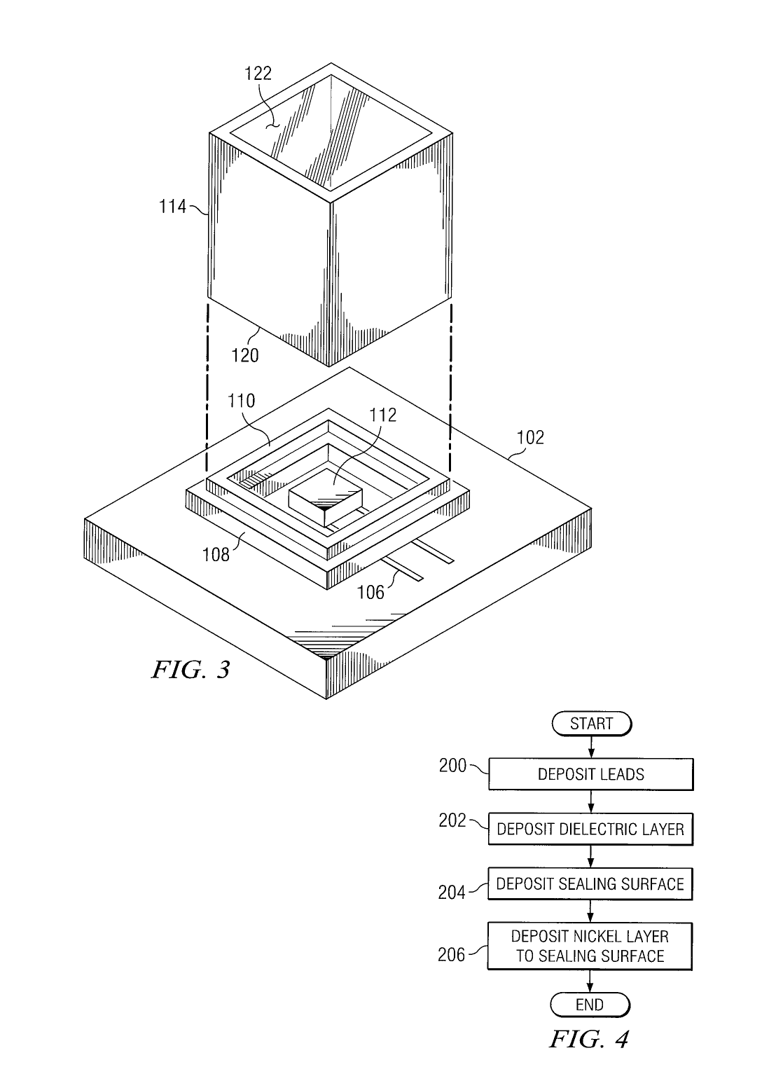

FIG. 3 illustrates an electrical component 112 that has been mounted onto substrate 100 as well as a cap 114 that may be placed over electrical component 112 and fused to sealing surface 110 according to an example embodiment of the present disclosure. Thus, by mounting electrical component 112 inside the contiguous shape created by sealing surface 110, placing cap 114 over electrical component 112, and fusing cap 114 to sealing surface 110, electrical component 112 may be enclosed in a sealed package comprising substrate 100 and cap 114. Furthermore, leads 106 may provide electrical communication between the enclosed area 116 of base 102 (e.g., the area located inside sealing surface 110) and the open area 118 of base 102 (e.g., the area located inside sealing surface 110).

Electrical component 112 may be any electrically-powered device or combination of two or more such devices operable to send or receive electrical current through leads 106 while residing inside cap 114. As an example and not by way of limitation, electrical component 112 may be an electrooptic device (e.g., an optical sensor or an optical emitter), a thermoelectric device consisting of a plurality of p-type and n-type elements, an electrical circuit, or any other suitable electrically powered device. In particular embodiments, leads 106 may supply power or control signals to electrical component(s) 112 residing inside sealing surface 110. As an example and not by way of limitation, leads 106 may be designed such that the power inputs to electrical component 112 may be mounted (e.g., soldered) directly onto leads 106. As another example and not by way of limitation, one or more wires extending from the power inputs of electrical component 112 may be soldered to one or more portions of leads 106 located inside sealing surface 110. One of ordinary skill in the art will appreciate that the present disclosure contemplates the use of any suitable means to couple leads 106 to an electrical component 112.

In particular embodiments, one or more constituent elements of electrical component 112 may be electrically interconnected to one another by patterned metallization 104 once electrical component 112 is mounted onto substrate 100. For example, the configuration of patterned metallization 104 may be tailored to match the configuration of the particular elements of electrical component 112 that need to be electrically interconnected with one another when electrical component 112 is mounted to substrate 100. Thus, once electrical component 112 has been mounted on substrate 100 and placed in contact with patterned metallization 104, patterned metallization 104 may electrically interconnect the constituent elements of electrical component 112. For example, if electrical component 112 is a thermoelectric device, patterned metallization 104 may electrically couple adjacent p-type and n-type elements of the thermoelectric device together.

By mounting cap 114 over the electrical components 112 located inside sealing surface 110, a manufacturer, user, or other party may seal electrical components 112 in an inert atmosphere or a vacuum. Cap 114 may be any rigid housing capable of creating a sealed environment around electrical component 112 when fused to sealing surface 110. For example, cap 114 may be a metal box that is welded, soldered or otherwise fused to sealing surface 110 to form an airtight seal. In particular embodiments, the fusion process used to attach cap 114 to sealing surface 110 may further include heat, force, electricity, or a combination thereof. Depending upon design, cap 114 may be composed of metal or a combination of metal and other materials (e.g., plastic, glass, etc.) suitable for the intended application of cap 114. For example, if electrical component 112 is an electrooptic device such as a photodetector, then cap 114 may include a window 122 of optically permissive material (e.g., glass, plastic, or diamond) to permit light to be transmitted to or from electrical component 112.

To facilitate the process of mounting cap 114 to sealing surface 110, cap 114 may include a perimeter edge 120 that corresponds in shape to the shape of sealing surface 110, though any suitable shape for perimeter edge 120 may be used as long as a complete seal is possible with sealing surface 110. Typically, the perimeter edge 120 of cap 114 is composed of metal to enable perimeter edge 120 to be fused (e.g., soldered or welded) to sealing surface 110. By enabling a cap 114 to be mounted over electrical components 112 located inside sealing surface 110, substrate 100 acts as the base to a sealed package while at the same time providing a foundation for leads 106 by which power may be supplied to the components located inside the cover through leads 106.

FIG. 4 illustrates an example process for manufacturing a substrate with interconnects and sealing surface. The method begins at step 200 where leads 106 are deposited on base 102. The method continues at step 202 where a layer of dielectric material (e.g., ceramic or glass) is deposited over a portion of leads 106 on base 102 to form dielectric layer 108. In particular embodiments, dielectric layer 108 may be deposited on base 102 in multiple steps. In a first step, a first layer of dielectric layer 108 may be deposited on base 102. The first layer of dielectric layer 108 may reach to the height of leads 106 such that the top of the first layer of dielectric layer 108 is flush with the top of leads 106. In a second step, a second layer of dielectric layer 108 may be deposited onto the first layer of dielectric layer 108, the second layer of dielectric layer 108 covering the top of leads 106. The method continues at step 204 where sealing surface 110 is applied to substrate 100. As mentioned above, sealing surface 110 may be deposited in a contiguous shape covering portions of dielectric layer 108 and/or base 102. The method continues at step 206 where a layer of nickel may be applied to sealing surface 110, after which, the method ends.

Although the present disclosure has been described in several embodiments, a myriad of changes, substitutions, and modifications may be suggested to one skilled in the art, and it is intended that the present disclosure encompass such changes, substitutions, and modifications as fall within the scope of the present appended example claim(s).

What is claimed is:

1. A method of manufacturing a substrate including a sealing surface and interconnects, comprising:
providing a base composed of a first electrically insulating material;
depositing at least one lead on the base, the at least one lead comprising a trace of electrically conductive material having a first end and a second end;
depositing a dielectric layer on a portion of the at least one lead between the first end and the second end, the dielectric layer comprising a coating of a second electrically insulating material;
depositing a sealing surface on a portion of the dielectric layer, the sealing surface comprising a contiguous shape of metal separating an enclosed area of the base located inside the contiguous shape from an open area of the base located outside the contiguous shape wherein:
the first end of the at least one lead is located in the enclosed area and the second end of the at least one lead is located in the open area; and
the dielectric layer electrically insulates the at least one lead from the sealing surface.

2. The method of claim 1, wherein the dielectric layer generally corresponds to the contiguous shape and separates the base and the at least one lead from the sealing surface.

3. The method of claim 2, further comprising:
mounting one or more electrical components to the base inside the enclosed area; and
coupling one of the one or more electrical components to the at least one lead.

4. The method of claim 3, further comprising providing a cap comprising a perimeter edge that generally corresponds in configuration to the contiguous shape.

5. The method of claim 4, further comprising:
placing the cap over the one or more electrical components; and
fusing the perimeter edge of the cap to the sealing surface.

6. The method of claim 5, wherein fusing the perimeter edge of the cap to the sealing surface comprises using heat to fuse the perimeter edge of the cap to the sealing surface.

7. The method of claim 1, wherein the base comprises a flexible material.

8. The method of claim 1, further comprising depositing a patterned metallization inside the sealed area that, once coupled to an electrical component, electrically interconnects one or more elements of the electrical component.

9. The method of claim 3, wherein the one or more electrical components comprise an electrooptic device.

10. The method of claim 4, wherein the cap comprises a window of generally transparent material operable to transmit light from a light source from a first side of the window to a second side of the window.

11. A system, comprising:
a base composed of a first electrically insulating material;
at least one lead deposited on the base, the at least one lead comprising a trace of electrically conductive material having a first end and a second end;
a dielectric layer deposited on a portion of the at least one lead between the first end and the second end, the dielectric layer comprising a coating of a second electrically insulating material;
a sealing surface deposited on a portion of the dielectric layer, the sealing surface comprising a contiguous shape of metal separating an enclosed area of the base located inside the contiguous shape from an open area of the base located outside the contiguous shape wherein:
the first end of the at least one lead is located in the enclosed area and the second end of the at least one lead is located in the open area; and
the dielectric layer electrically insulates the at least one lead from the sealing surface.

12. The system of claim 11, wherein the dielectric layer generally corresponds to the contiguous shape and separates the base and the at least one lead from the sealing surface.

13. The system of claim 12, further comprising one or more electrical components mounted to the base inside the enclosed area and coupled to the at least one lead.

14. The system of claim 13, further comprising a cap comprising a perimeter edge that generally corresponds in configuration to the contiguous shape.

15. The system of claim 14, wherein the cap is placed over the one or more electrical components and fused to the sealing surface.

16. The system of claim 15, wherein the one or more electrical components comprise a thermoelectric device; and further comprising:
a patterned metallization deposited on the base inside the sealed area that electrically interconnects one or more adjacent thermoelectric elements of the thermoelectric device.

17. The system of claim 15, wherein the one or more electrical components comprise an electrooptic device; and
the cap comprises a window of generally transparent material operable to transmit light from a light source from a first side of the window to a second side of the window.

18. The system of claim 11, wherein the first electrically insulating material is flexible.

19. A method of using a substrate including a sealing surface and interconnects, comprising:
providing a base composed of a first electrically insulating material, the base comprising:
at least one lead deposited on the base, the at least one lead comprising a trace of electrically conductive material having a first end and a second end;
a dielectric layer deposited on a portion of the at least one lead between the first end and the second end, the dielectric layer comprising a coating of a second electrically insulating material;
a sealing surface deposited on a portion of the dielectric layer, the sealing surface comprising a contiguous shape of metal separating an enclosed area of the base located inside the contiguous shape from an open area of the base located outside the contiguous shape wherein the first end of the at least one lead is located in the enclosed area and the second end of the at least one lead is located in the open area, and the dielectric layer electrically insulates the at least one lead from the sealing surface;
one or more electrical components mounted to the base inside the enclosed area and coupled to the at least one lead; and
a cap placed over the one or more electrical components and fused to the sealing surface; and
communicating electrical current with the one or more electrical components through the at least one lead.

20. The method of claim 19 wherein the electrical current comprises an information signal.
